(19) United States
(12) Patent Application Publication
(10) Pub. No.: US 2025/0029837 A1
(43) Pub. Date: Jan. 23, 2025

(54) METHODS AND COMPOSITIONS FOR TRENCH FORMATION USING ADVANCED TRACK-BASED PATTERNING PROCESSES

(71) Applicant: Tokyo Electron Limited, Tokyo (JP)

(72) Inventors: David Conklin, Saratoga Spring, NY (US); Charlotte Cutler, Albany, NY (US); Michael Murphy, Niskayuna, NY (US); Jodi Grzeskowiak, Schenectady, NY (US)

(21) Appl. No.: 18/908,557

(22) Filed: Oct. 7, 2024

Related U.S. Application Data
(63) Continuation-in-part of application No. 18/615,313, filed on Mar. 25, 2024.
(63) Continuation-in-part of application No. 18/617,951, filed on Mar. 27, 2024.
(60) Provisional application No. 63/555,246, filed on Feb. 19, 2024.
(60) Provisional application No. 63/603,580, filed on Nov. 28, 2023.
(60) Provisional application No. 63/472,910, filed on Jun. 14, 2023.
(60) Provisional application No. 63/603,580, filed on Nov. 28, 2023.

(51) Int. Cl. H01L 21/027; C09K 13/00

(52) U.S. Cl. CPC H01L 21/0274; C09K 13/00

(57) ABSTRACT

A method for forming a semiconductor device can include coating a reversible overcoat layer over first mandrels on a substrate, inducing a crosslinking reaction within the reversible overcoat layer that renders the reversible overcoat layer insoluble to a developer and forms a crosslinked overcoat layer, diffusing acid particles from the first mandrels into first portions of the crosslinked overcoat layer, inducing a de-crosslinking reaction within the first portions of the crosslinked overcoat layer to form de-crosslinked regions, where unmodified regions of the crosslinked overcoat layer form second mandrels, and selectively removing the de-crosslinked regions with the developer such that the first mandrels and the second mandrels form a mandrel pattern over the substrate, where the developer has a solubility distance in a range of zero to seven in a Hansen Solubility Parameter space relative to methyl isobutyl carbinol.

### CROSS-REFERENCE TO RELATED APPLICATIONS

This application claims priority to and the benefit of (1) U.S. Provisional Application No. 63/555,246, filed on Feb. 19, 2024 and (2) U.S. Provisional Application No. 63/603,580, filed on Nov. 28, 2023, both of which applications are hereby incorporated herein by reference in their entirety. This application is a continuation-in-part of, claims priority to, and claims the benefit of (1) U.S. application Ser. No. 18/615,313, filed on Mar. 25, 2024, and (2) U.S. application Ser. No. 18/617,951, filed on Mar. 27, 2024, both of which applications are hereby incorporated herein by reference in their entirety.

### TECHNICAL FIELD

The present disclosure relates generally to methods for manufacturing semiconductor devices, and more particularly, developer compositions for sub-resolution-lithography patterning in methods for manufacturing semiconductor devices.

### BACKGROUND

In material processing methodologies, such as photolithography, creating patterned layers typically involves the application of a thin layer of radiation-sensitive material (such as photoresist) to an upper surface of a substrate. This radiation-sensitive material can be transformed into a patterned mask that can be used to etch or transfer a pattern into an underlying layer of the substrate. Patterning of the radiation-sensitive material generally involves exposure by a radiation source through a reticle (and associated optics) onto the radiation-sensitive material using, for example, a photolithographic exposure system. This exposure can create a latent pattern within the radiation-sensitive material that can then be developed. “Developing” can refer to dissolving and removing a portion of the radiation-sensitive material to yield a relief pattern (topographic pattern). The portion of material removed can be either the irradiated regions or the non-irradiated regions of the radiation-sensitive material, depending on the material's photoresist tone (positive or negative) and/or the type of developing solvent used. The relief pattern can then function as a mask layer defining a pattern.

Application and development of various films used for patterning can include thermal treatment, or “baking.” For example, a newly applied film can receive a post-application bake (PAB) to evaporate solvents and/or to improve material properties, such as structural rigidity or etch resistance. A post-exposure bake (PEB) can be executed to set a given pattern and limit or prevent unintended removal of material. Fabrication tools for coating and developing substrates typically include one or more baking modules.

Some photolithography processes include coating with a photoresist, and then exposing the substrate to a pattern of light to create a relief pattern for use as a mask or template for additional processing, such as transferring the pattern into an underlying layer. In related photolithography processes, the substrate may be coated with a thin film of bottom anti-reflective coating (BARC) before coating with a photoresist and then exposing the substrate. These processes can serve as discrete operations in the fabrication of microchips.

### SUMMARY

In accordance with an embodiment of the present disclosure, for a developer configured to selectively remove a solubility switched region of a layer of a first material during a semiconductor manufacturing process for forming a mandrel pattern in the layer on a substrate, the developer can have a solubility distance in a range of zero to seven in a Hansen Solubility Parameter (HSP) space relative to methyl isobutyl carbinol (MIBC).

In accordance with an embodiment of the present disclosure, a method for forming a semiconductor device can include: coating a reversible overcoat layer over first mandrels on a substrate; inducing a crosslinking reaction within the reversible overcoat layer that renders the reversible overcoat layer insoluble to a developer and forms a crosslinked overcoat layer; diffusing acid particles from the first mandrels into first portions of the crosslinked overcoat layer; inducing a de-crosslinking reaction within the first portions of the crosslinked overcoat layer to form de-crosslinked regions, where unmodified regions of the crosslinked overcoat layer form second mandrels; and selectively removing the de-crosslinked regions with the developer such that the first mandrels and the second mandrels form a mandrel pattern over the substrate, where the developer has a solubility distance in a range of zero to seven in a Hansen Solubility Parameter space relative to methyl isobutyl carbinol (MIBC).

In accordance with an embodiment of the present disclosure, a method of formulating a developer for developing a patterning material having a reversible solubility in a process of manufacturing a semiconductor device can be provided that includes: identifying a list of materials in which each individual material of the list of the materials has a dispersion component between 14 and 18, a polar component of between 2 and 8, and a hydrogen bonding component of between 7 and 16 according to a Hansen Solubility Parameter (HSP) component system; and selecting a combination of two or more of the materials from the list and mixing the selected combination of the two or more materials at a ratio to formulate the developer such that the developer has a combined solubility distance in a range of zero to seven in an HSP space relative to methyl isobutyl carbinol (MIBC).

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1A-1I illustrate cross-sectional views of different stages of a method for forming a mandrel pattern in accordance with an embodiment of the present disclosure;

FIG. 2 illustrates a flowchart of a method for forming a mandrel pattern in accordance with an embodiment of the present disclosure;

FIG. 3 is a three-dimension (3D) graph illustrating a Hansen Solubility Parameter (HSP) space in accordance with an embodiment of the present disclosure;

FIG. 4 is a screenshot from a computer program providing a list of materials including HSP information for each listed material, in accordance with an embodiment of the present disclosure;

FIG. 5 is a flowchart of a method of selecting a developer in accordance with an embodiment of the present disclosure; and

FIG. 6 is a screenshot from a computer program providing an example combination of materials including HSP information for each listed material, in accordance with an embodiment of the present disclosure.

### DETAILED DESCRIPTION OF ILLUSTRATIVE EMBODIMENTS

Referring now to the drawings, in which like reference numbers can be used herein to designate like or similar elements throughout the various views, illustrative and example embodiments are shown and described. The figures are not drawn to scale, and in some instances the drawings are exaggerated or simplified in places for illustrative purposes. One of ordinary skill in the art can appreciate many possible applications and variations for other embodiments based on the following illustrative and example embodiments provided in the present disclosure.

In some embodiments of the present disclosure, a developer can be configured to selectively remove a de-crosslinked region of a reversible overcoat layer during a semiconductor manufacturing process for forming a mandrel pattern on a substrate, where the developer has a solubility distance in a range of zero to seven in a Hansen Solubility Parameter (HSP) space relative to methyl isobutyl carbinol (MIBC). In some embodiments of the present disclosure, a method for forming a semiconductor device can include: coating a reversible overcoat layer over first mandrels on a substrate; inducing a crosslinking reaction within the reversible overcoat layer that renders the reversible overcoat layer insoluble to a developer and forms a crosslinked overcoat layer; diffusing acid particles from the first mandrels into first portions of the crosslinked overcoat layer; inducing a de-crosslinking reaction within the first portions of the crosslinked overcoat layer to form de-crosslinked regions, wherein unmodified regions of the crosslinked overcoat layer form second mandrels; and selectively removing the de-crosslinked regions with the developer such that the first mandrels and the second mandrels form a mandrel pattern over the substrate, where the developer has a solubility distance in a range of zero to seven in a Hansen Solubility Parameter space relative to methyl isobutyl carbinol (MIBC). Some example embodiments of the present disclosure are described in more detail below with reference to the drawings in the present disclosure, to describe some example variations for some embodiments of the present disclosure. Other embodiments can also be understood from the entirety of the specification and the claims herein.

In the present disclosure, terms such as “first”, “second”, and the like, may be used to describe various components, but the components are not necessarily limited by such terms, for example, regarding order, sequence, importance, or number of such components possible in an embodiment. Such terms can be used merely for the purpose of distinguishing one component from other components in a given embodiment or group of embodiments. For example, a first component may be referred to as a second component, and similarly, a second component may also be referred to as a first component without departing from the scopes of rights according to the present disclosure. Because semiconductor geometries and sizes can be so extremely small (e.g., on the order of 1 to 5 nm), the terms “film” and “layer” may be used interchangeably herein.

Ever continuous scaling can require improved patterning resolution. One approach is spacer technology to define a sub-resolution line feature via atomic layer deposition (ALD). One challenge, however, is that if the opposite tone feature is desired, using spacer techniques can involve a complex succession of operations, including over-coating with another material (an “overcoat”), using the spacer features as mandrels, chemical mechanical planarization (CMP), and reactive ion etch (RIE) to exhume the spacer material leaving a narrow trench, which can be costly.

In such cases, spacer techniques can involve a complex and costly succession of steps, including over-coating with another material (an “overcoat”) using the spacer features as mandrels, chemical-mechanical planarization (CMP) to reveal the spacer features, and reactive ion etching (RIE) to remove the spacer material, leaving a narrow trench.

Anti-spacer technology is an alternate, self-aligned approach that uses the diffusion length of a reactive species across the boundary between the overcoat and an adjacent layer to define a critical dimension (CD), creating a narrow trench around the features of that adjacent layer after development of the overcoat. When generation of the reactive species is controlled spatially via exposure through a mask, finer features can be formed, such as a narrow slot contact. The CD itself can be tuned based on the physical and chemical properties of the reactive species (e.g., its molecular weight and affinity for interactions with the host material) and by modifying the bake temperature and bake time in a post exposure bake (PEB). As a result, anti-spacer techniques can enable patterning narrow slot-contact features at dimensions beyond the reach of advanced lithographic capabilities.

Anti-spacer formation can achieve self-aligned double patterning (SADP) through spin-on processes, thereby improving throughput and overall cost. Limitations of conventional SADP processes, such as resolving a single CD across an entire substrate, can be overcome with anti-spacer processes. Because features can be formed by the physical generation and subsequent diffusion of a solubility-changing species across an interface, the formation and mobility of the diffusing species can be modulated across the substrate to enable multiple feature widths in a single process. The density of the final pattern, however, can be limited within anti-spacer flows exhibiting change in CD of a single mandrel, as can be particularly apparent when the final target pitch is approaching one-half the resolution limit of the lithographic exposure. To achieve a 1:1 line-space (L/S) mandrel pattern (e.g., equal pitch between mandrels), the initial lithographic exposure can be biased to account for the addition of a mandrel or anti-spacer and achieve the target pitch.

When the target pitch approaches one-half the resolution limit of the lithographic exposure, the correct bias can be no longer resolvable, and additional post-exposure processes may be needed. Resolution limitation of the employed lithographic technology can prevent desired biasing of the incoming L/S pattern to enable symmetrical L/S patterning, which can result in asymmetrical L/S patterning post-multi-patterning processing. In particular, some features can remain limited by the resolution of the photolithography process.

Example embodiments described in the present disclosure can provide compositions and formulations for a developer or solvent for use in an anti-spacer patterning scheme to achieve sub-lithographic mandrel patterns. Such scheme can rely on diffusion of a solubility-changing species outward from the photoresist mandrels into the reversible overcoat to cause a reaction resulting in the formation of narrow trenches. The resulting process flow can overcome the pitch limitation of an acid-in unidirectional diffusion process flow using a post-lithographic trim of the photoresist mandrels to resolve the required bias of the line-space pattern to achieve a final symmetrical mandrel pattern.

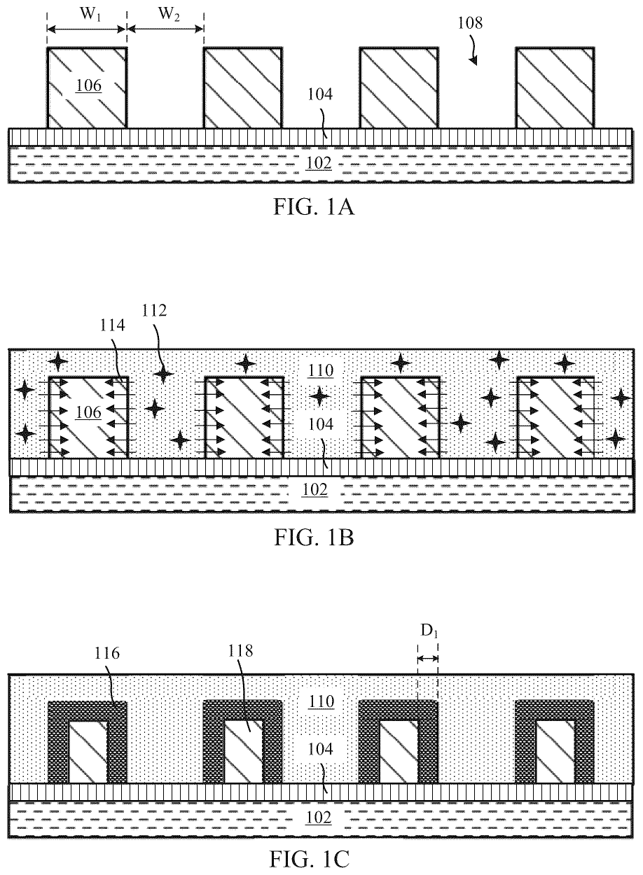

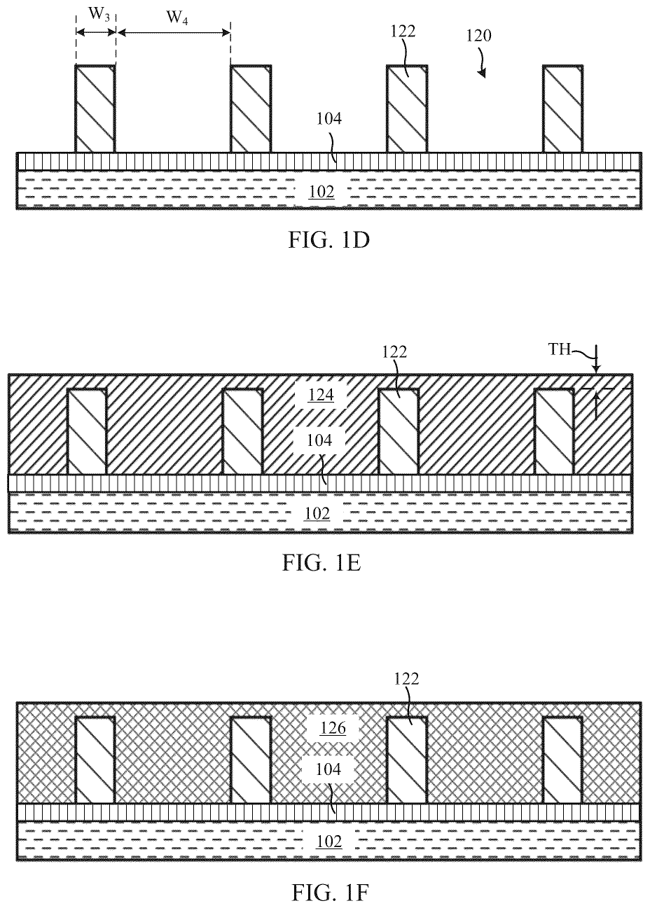

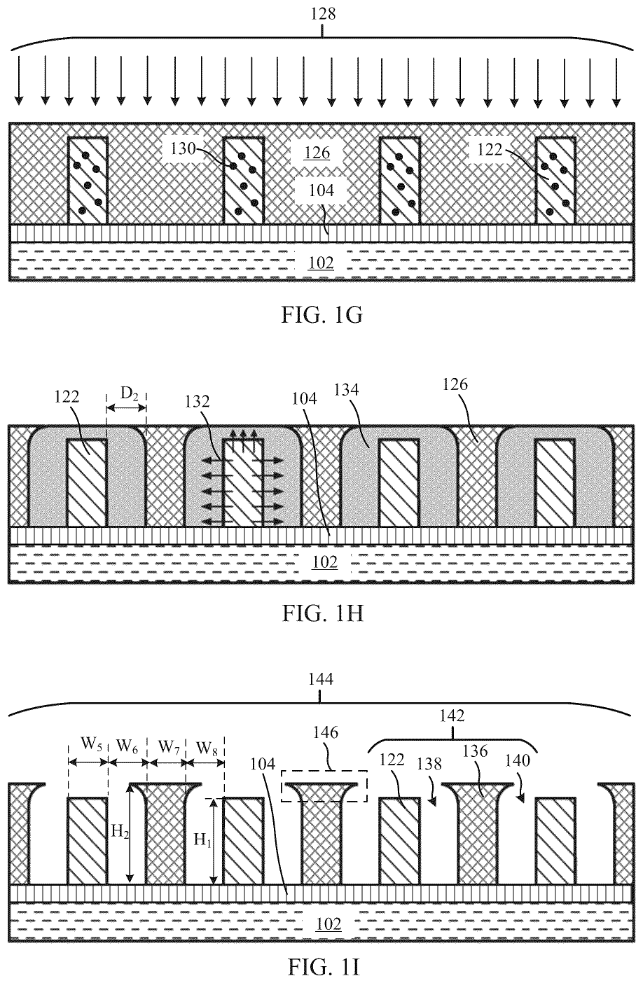

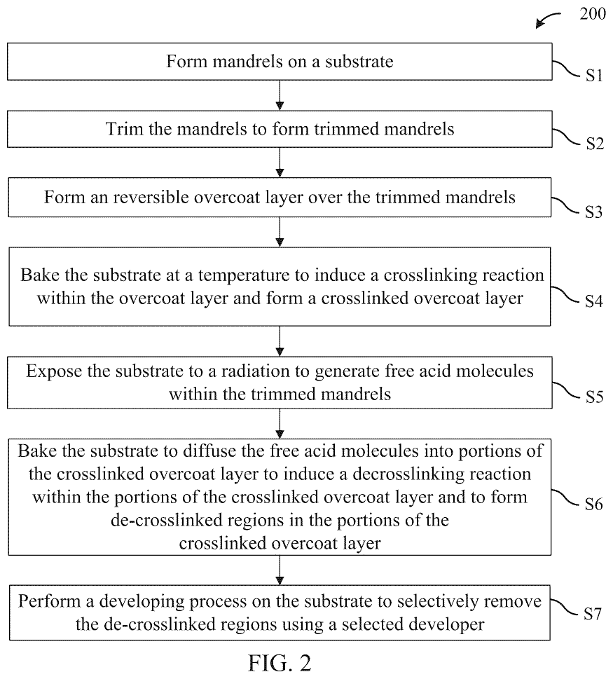

FIGS. 1A-1I illustrate cross-sectional views of different stages of an example method for forming a mandrel pattern for a pitch-splitting process flow illustrated in FIG. 2.

Referring to FIG. 1A, mandrels 106 can be formed over a substrate 102 (Box S1 of FIG. 2). The substrate 102 can be a part of, or include, a semiconductor device or a semiconductor structure, and can be formed in any suitable manner, including using any suitable combination of wet and/or dry deposition, photolithography, and etch techniques. For example, the semiconductor structure can include the substrate 102 in which various device regions are formed. In an embodiment, the substrate 102 can include isolation regions such as shallow trench isolation (STI) regions, diffusion regions, as well as other regions formed therein.

The substrate 102 can include layers of semiconductors suitable for various microelectronics. In an embodiment, the substrate 102 can be a silicon wafer, or a silicon-on-insulator (SOI) wafer, for example. In an embodiment, the substrate 102 can include a silicon germanium wafer, silicon carbide wafer, gallium arsenide wafer, gallium nitride wafer, or other compound semiconductors, for example. In an embodiment, the substrate 102 can include heterogeneous layers such as silicon germanium on silicon, gallium nitride on silicon, silicon carbon on silicon, or layers of silicon on a silicon or SOI substrate, for example. In an embodiment, the substrate 102 can be patterned or embedded in other components of the semiconductor device or the semiconductor structure.

Referring further to FIG. 1A, in an embodiment, an intermediate layer 104 can be formed over the substrate 102 such that the mandrels 106 are formed over the intermediate layer 104. The intermediate layer 104 can be a target for pattern transfer in subsequent processing after formation of the mandrel pattern 144 (see FIG. 1I) is completed. The intermediate layer 104 can include silicon, silicon oxynitride, organic material, non-organic material, amorphous carbon, or the like, for example. The intermediate layer 104 can be selected to have anti-reflective properties, such as by using a silicon bottom anti-reflective coating (Si-BARC), for example. The intermediate layer 104 can be a mask layer including a hard mask. The intermediate layer 104 can be a stacked hard mask including, for example, two or more layers of two or more different materials. For example, in an embodiment where the hard mask includes two layers, a first layer of the hard mask can include a metal-based layer such as titanium nitride, titanium, tantalum nitride, tantalum, tungsten-based compounds, ruthenium-based compounds, or aluminum-based compounds, and a second layer of the hard mask can include a dielectric layer such as silicon dioxide, silicon nitride, silicon oxynitride, silicon carbide, amorphous silicon, or polycrystalline silicon. The intermediate layer 104 can be deposited using any suitable deposition process(es). For example, suitable deposition processes can include a spin-on coating process, a chemical vapor deposition (CVD) process, an atomic layer deposition (ALD) process, plasma deposition processes (e.g., a plasma-enhanced CVD (PECVD) process, or a plasma-enhanced ALD (PEALD) process), and/or other layer deposition processes or combinations of processes.

In an embodiment, the mandrels 106 can be formed by forming a photoresist layer (not shown) over the intermediate layer 104 and patterning the photoresist layer using any suitable photolithographic technique(s). For example, the photoresist layer can include a positive-tone photoresist or a negative-tone photoresist. In the illustrated example embodiment, the photoresist layer can include a positive-tone chemically amplified photoresist (CAR). The photoresist layer can be deposited on the substrate 102 in any suitable manner. For example, the photoresist layer can be deposited by spin-coating, spray-coating, dip-coating, or roll-coating. As a particular example, the photoresist layer can be deposited on the substrate 102 using a spin-on deposition technique, which can be also referred to as spin-coating. In an embodiment, the photoresist layer can include an agent-generating ingredient that, in response to a suitable agent-activation trigger (e.g., heat and/or radiation), generates a solubility-changing agent (e.g., an acid). Example agent-generating ingredients can include a thermal-acid generator (TAG) that is configured to generate an acid in response to heat or a photo-acid generator (PAG) that is configured to generate an acid in response to actinic radiation.

With spin-on deposition, a particular material (e.g., a material of the photoresist layer) can be deposited on the substrate 102 (e.g., on the intermediate layer 104 can be formed on the substrate 102). The substrate 102 then can be rotated (if not already rotating, possibly at a relatively low velocity) at a relatively high velocity so that centrifugal force causes the deposited material to move toward edges of the substrate 102, thereby coating the substrate 102. Excess material is typically spun off the substrate 102. In an embodiment, the spin-on deposition technique can include dispensing liquid chemicals onto the substrate 102 (e.g., on a top surface of the intermediate layer 104) using a coating module with a liquid delivery system that can dispense one or more types of liquid chemicals. The dispense volume can be in a range from 0.2 mL to 10 mL, for example, in a range from 0.5 mL to 2 mL. The substrate 102 can be secured to a rotating chuck that supports the substrate 102. The rotating speed during the liquid dispense can be in a range from 50 rpm to 3000 rpm, for example, in a range from 1000 rpm to 2000 rpm. The system also can include an anneal module that can bake or apply light radiation to the substrate 102 after the chemicals have been dispensed. It can be understood that this example spin-on deposition technique and associated values are provided as examples only. In an embodiment, the photoresist layer can be deposited using a CVD process, a plasma-enhanced CVD process, an ALD process, or other suitable processes.

After forming the photoresist layer, a reticle (not shown) can be positioned over the photoresist layer. The reticle can be used to modulate a dose (or an intensity) of a radiation (e.g., actinic radiation) that can be used to expose the photoresist layer. The reticle can include regions of different transparency to the radiation (e.g., opaque and transparent regions). The photoresist layer then can be subject to an exposure step through the reticle. The radiation can expose exposed regions of the photoresist layer while unexposed (or unmodified) regions of the photoresist layer can be protected by the reticle. The exposure step can be performed using a photolithographic technique such as dry lithography (e.g., using 193-nanometer dry lithography), immersion lithography (e.g., using 193-nanometer immersion lithography), i-line lithography (e.g., using 365-nanometer wavelength UV radiation for exposure), H-line lithography (e.g., using 405-nanometer wavelength UV radiation for exposure), extreme UV (EUV) lithography, deep UV (DUV) lithography, or any suitable photolithography technology, for example.

In an embodiment, the radiation can generate an acid in the exposed regions of the photoresist layer. The acid can be generated from a PAG that can be present in the photoresist layer under the influence of the radiation. The acid can react with the material of the photoresist layer and alter the solubility of the exposed regions of the photoresist layer. Subsequently, the exposed regions of the photoresist layer can be removed by performing a developing process using a suitable developer. The developing process can form openings 108 in the photoresist layer that expose portions of the intermediate layer 104. The unexposed regions of the photoresist layer can form the mandrels 106.

The mandrels 106 can have a first width W1 and the openings 108 can have a second width W2. In an embodiment, the first width W1 and/or the second width W2 can have smallest values that are achievable by photolithographic techniques. In the illustrated example embodiment, a ratio W1:W2 can equal 1:1, for example.

Referring to FIG. 1B, an overcoat layer 110 can be deposited over the substrate 102 in any suitable manner. For example, the overcoat layer 110 can be deposited by spin-coating, spray-coating, dip-coating, or roll-coating. As a particular example, the overcoat layer 110 can be deposited on the substrate 102 using a spin-on deposition technique, which can be also referred to as spin-coating. The spin-on deposition technique has been described above with reference to FIG. 1A and the description is not repeated here. The overcoat layer 110 can be also referred to as a trim layer. The overcoat layer 110 can fill the openings 108 (see e.g., FIG. 1A) and cover top surfaces of the mandrels 106 (see e.g., FIG. 1B).

A material for the overcoat layer 110 can be chosen such that the overcoat layer 110 can be removed in a subsequent developing process, as described below in greater detail. In an embodiment, the overcoat layer 110 can be a multicomponent material that, as deposited, includes a first component and a second component. The first component can be, for example, a polymer. The second component can be, for example, a solubility-changing agent 112, such as an acid (e.g., a free acid). In the illustrated example embodiment, the solubility-changing agent 112 can include a plurality of acid particles, which are depicted as filled 4-pointed stars in FIG. 1B. The second component can be, as another example, an agent-generating ingredient that, in response to a suitable agent-activation trigger (e.g., heat or radiation), generates a solubility-changing agent (e.g., an acid). Example agent-generating ingredients can include a TAG that is configured to generate an acid in response to heat or a PAG that is configured to generate an acid in response to actinic radiation.

For example, in the case of an overcoat layer 110 including a free acid, a solubility-changing agent 112 can be the free acid and subsequent baking of the substrate 102 can cause the free acid to diffuse (as indicated by arrows 114 in FIG. 1B) into perimeter portions of the mandrels 106 and can cause the perimeter portions of the mandrels 106 to become soluble in a developer.

As another example, in the case of the overcoat layer 110 including a TAG as an agent-generating ingredient, subsequent baking of the substrate 102 can cause the TAG to generate a solubility-changing agent 112 (e.g., acid), which can be referred to as activating the acid, can cause the generated solubility-changing agent 112 to diffuse (as indicated by arrows 114 in FIG. 1B) into perimeter portions of the mandrels 106, and can cause the perimeter portions of the mandrels 106 to become soluble in a developer.

As another example, in the case of the overcoat layer 110 including a PAG as an agent-generating ingredient, an exposure step that includes exposing the overcoat layer 110 to a radiation (e.g., actinic radiation) can be performed prior to baking the substrate 102. The exposure step can cause the PAG to generate a solubility-changing agent 112 (e.g., acid), which can be referred to as activating the acid. Baking of the substrate 102 can cause the generated solubility-changing agent 112 to diffuse (as indicated by arrows 114 in FIG. 1B) into perimeter portions of the mandrels 106 and can cause the perimeter portions of the mandrels 106 to become soluble in a developer.

Referring to FIG. 1C, a baking process can be performed on the substrate 102. In an embodiment, the baking process can be a thermal process that is performed by heating the substrate 102 in a process chamber to a temperature between 50° C. and 250° C., for example, between 60° C. and 140° C. in certain embodiments, in vacuum or under a gas flow. In a particular example, the substrate 102 can be baked for a duration in a range from 1 to 3 minutes. The bake conditions can be selected to promote the diffusion of the solubility-changing agent 112 (and possibly generation of the solubility-changing agent 112 from an agent-generating ingredient of the overcoat layer 110, if applicable) and associated change in solubility of the perimeter regions of the mandrels 106 (see FIG. 1B) to a target first depth D1. The first depth D1 can be tuned by parameters of the baking process (such as, for example, a bake temperature and a bake duration) and material parameters (such as, for example, a polymer composition of the mandrels 106, and an acid composition and an acid concentration in the overcoat layer 110).

Referring to FIG. 1C, the solubility-changing agent 112 can chemically react with a material of the mandrels 106 to form modified regions 116 of the mandrels 106. Such chemical reaction can change the solubility of the modified regions 116 of the mandrels 106 so that the modified regions 116 of the mandrels 106 can be removed in a subsequent developing process. Each modified region 116 can extend along sidewalls and a top surface of an unmodified region 118 of a respective mandrel 106 (see FIG. 1C).

Referring to FIG. 1D, a developing process can be performed on the substrate 102 using a suitable developer. In an embodiment, the developer can include a metal ion-free (MIF) developer, for example, an aqueous solution of tetramethylammonium hydroxide (TMAH). In an embodiment, the developer solution can include a metal ion-containing developer, for example, an aqueous solution of sodium hydroxide (NaOH) or potassium hydroxide (KOH). In an embodiment, the developing process can include dipping or soaking the substrate 102 in the developer.

In an embodiment, the developer can remove the overcoat layer 110 (see FIG. 1C) and the modified regions 116 (see FIG. 1C), and form openings 120 that expose the intermediate layer 104 (see e.g., FIG. 1D). Remaining unmodified regions 118 (see FIG. 1C) of the mandrels 106 can form trimmed mandrels 122 over the intermediate layer 104. The operations described using FIGS. 1B-1D can be collectively described as a trim process or forming trimmed mandrels (Box S2 of FIG. 2).

The trimmed mandrels 122 can have a third width W3 and the openings 120 can have a fourth width W4. The third width W3 of the mandrels 122 can be less than the first width W1 of the mandrels 106 (e.g., compare FIG. 1A). In an embodiment, when the first width W3 is less than the smallest value achievable by the photolithography process, the trimmed mandrels 122 can have a sub-lithographic width. The fourth width W4 of the openings 120 is greater than the second width W2 of the openings 108 (e.g., compare FIG. 1A). In the illustrated example embodiment, a ratio W3:W4 can equal 1:3. Such a pattern of the trimmed mandrels 122 can be also referred to as a 1:3 line-space (L/S) pattern. In an embodiment, a ratio W3:W4 can be in a range from 1:2 to 1:5.

Referring to FIG. 1E, an overcoat layer 124 can be deposited over the substrate 102 in any suitable manner (Box S3 of FIG. 2). For example, the overcoat layer 124 can be deposited by spin-coating, spray-coating, dip-coating, or roll-coating. As a particular example, the overcoat layer 124 can be deposited on the substrate 102 using a spin-on deposition technique, which can be also referred to as spin-coating. The spin-on deposition technique has been described above with reference to FIG. 1A and the description is not repeated here. The overcoat layer 124 can be also referred to as a reversible overcoat (ROC) layer. The overcoat layer 124 can fill the openings 120 (see FIG. 1D) and cover top surfaces of the trimmed mandrels 122 (see FIG. 1E). The overcoat layer 124 can have a thickness TH over the top surfaces of the trimmed mandrels 122.

A material of the overcoat layer 124 can be selected not to intermix with a material of the trimmed mandrels 122. The material of the overcoat layer 124 can include various solutes in an application-specific organic solvent system, for example.

In an embodiment, the material of the overcoat layer 124 can include a first solute and a second solute in a solvent. The first solute can include a moiety capable of reacting with a moiety of a second solute to create an acetal bond (or “crosslink”). Such moieties in one solute can include an organic hydroxy functional group or a carboxylic acid functional group, and in the other solute, such moieties can be an enol ether functional group (e.g., a vinyl ether) or an N-methoxymethylamide functional group. In an embodiment, the solutes can possess multiple functional groups capable of crosslinking. In an embodiment, additional solutes can be included in the composition, such as a third solute including a weak acid that catalyzes the crosslinking reaction (“catalyst”).

In an embodiment, one solute can be a polymer and the other can be a small molecule with mass below 1000 daltons. In such cases, the small molecule can be referred to as a “crosslinking agent” or “crosslinker.” In an embodiment, both solutes can be polymers, and the solute present in the composition in lower abundance can be referred to as the cross-linking agent, while that present in greater abundance can be referred to simply as “the polymer.” In an embodiment in which the solutes are present in equal abundance, the solute including enol ether or N-methoxmethylamide functional groups can be referred to as the crosslinking agent, while the other solute can be referred to simply as “the polymer.”

The crosslinking agent can have a function of reacting with the polymer to promote hardening of the composition of the overcoat layer 124. The crosslinking agent can further enable formation of an insoluble network via the formation of acetal bonds between the crosslinking agent and the polymer.

A catalyst present in an embodiment can function to decrease an activation energy to initiate crosslinking (e.g., lower bake temperature and/or reduce bake time). A catalyst can include a sulfonic acid such as p-toluenesulfonic acid (pTSA), dodecylbenzenesulfonic acid, a mixture thereof, or the like. In an embodiment, the catalyst can be omitted.

Referring to FIG. 1F, after depositing the overcoat layer 124, a baking process can be performed on the substrate 102 to induce crosslinking within the overcoat layer 124, thereby making the crosslinked overcoat layer 126 insoluble in a subsequently used developer (Box S4 in FIG. 2). In an embodiment, the baking process can be a thermal process that is performed by heating the substrate 102 in a process chamber to a temperature between 50° C. and 300° C., in vacuum or under a gas flow. In an embodiment, the baking can be performed at a temperature less than 150° C. for less than 6 minutes, for example.

Referring to FIG. 1G, agent-generating ingredients within the trimmed mandrels 122 can be decomposed to generate a solubility-changing agent 130 (e.g., free acid) (Box S5 in FIG. 2). In the illustrated example embodiment, the solubility-changing agent 130 can include acid particles that are depicted as filled circles in FIG. 1G. In an embodiment where the agent-generating ingredients include a PAG, the solubility-changing agent 130 (e.g., free acid) can be generated in response to exposing the mandrels 122 to a radiation 128 (e.g., actinic radiation). In an embodiment, the substrate 102 can be flood exposed to the radiation 128. In such embodiments, each mandrel 122 can include a substantively similar amount of the solubility-changing agent 130 (e.g., free acid).

Referring to FIG. 1H, a baking process can be performed on the substrate 102 (Box S6 in FIG. 2). The baking process can diffuse (as indicated by arrows 132 in FIG. 1H) the solubility-changing agent 130 out of the mandrels 122, across interfaces between the mandrels 122 and the crosslinked overcoat layer 126 and into the crosslinked overcoat layer 126 causing de-crosslinking reactions within the crosslinked overcoat layer 126 to a target second depth D2 to form de-crosslinked regions 134. The de-crosslinked regions 134 can be also referred to as anti-spacers. In an embodiment, the baking process can be a thermal process that is performed by heating the substrate 102 in a process chamber to a temperature between 50° C. and 300° C., in vacuum or under a gas flow. In an embodiment, the baking can be performed at a temperature less than 150° C. for less than 6 minutes, for example.

The second depth D2 can be tuned by parameters of the baking process (such as, for example, a bake temperature and/or a bake duration) and/or material parameters (such as, for example, a polymer composition of the crosslinked overcoat layer 126, and an acid composition and an acid concentration in the mandrels 122). In an embodiment, the second depth D2 and the thickness TH of the overcoat layer 124 (see FIG. 1E) can be tuned such that the second depth D2 is greater than the thickness TH. In such cases, the solubility-changing agent 130 (see FIG. 1G) can diffuse (as indicated by arrows 132 in FIG. 1H) from the top surfaces of the mandrels 122 to a top surface of the crosslinked overcoat layer 126, such that top surfaces of the de-crosslinked regions 134 are exposed and can be level with a top surface of the crosslinked overcoat layer 126.

Referring to FIG. 1I, a developing process can be performed on the substrate 102 using a suitable developer (Box S7 in FIG. 2). The suitable developer can include an organic solvent that is selective to removing the de-crosslinked regions 134 (see FIG. 1H). In an embodiment, a solubility of the de-crosslinked regions 134 in the suitable developer can be greater than a solubility of the crosslinked overcoat layer 126 in the suitable developer and a solubility of the trimmed mandrels 122 in the suitable developer. The developing process can selectively remove the de-crosslinked regions 134 to form first and second openings 138 and 140 that expose the intermediate layer 104. Remaining regions of the crosslinked overcoat layer 126 can form secondary mandrels 136. The trimmed mandrels 122 and the secondary mandrels 136 can form a mandrel pattern 144 on the substrate 102. In an embodiment, the trimmed mandrels 122 can have a first height H1 and the secondary mandrels 136 can have a second height H2, with the second height H2 being greater than the first height H1. In an embodiment, a width of the secondary mandrels 136 can increase as the secondary mandrels 136 extend away from the substrate 102. In such embodiments, the secondary mandrels 136 can include overhang regions 146 that overhang the first and the second openings 138 and 140.

In an embodiment, the mandrel pattern 144 can include mandrel patterns 142. Each mandrel pattern 142 can include first and second mandrels 122 and 136, and first and second openings 138 and 140, with the first opening 138 being interposed between the first mandrel 122 and the second mandrel 136, and the second mandrel 136 being interposed between the first opening 138 and the second opening 140. The first mandrel 122 can have a fifth width W5, the second mandrel 136 can have a seventh width W7, the first opening 138 can have a sixth width W6, and the second opening 140 can have a width W8. In the illustrated example embodiment, a ratio W5:W6:W7:W8 can equal 1:1:1:1. In such embodiments, the mandrel pattern 144 can be also referred to as a 1:1:1:1 L/S pattern. In other embodiments, the ratio W5:W6:W7:W8 can be equal to 1:X:(3−2X):X, where X is the second depth D2 as measured in units of the fifth width W5, with X being in a range from 0 to 3/2. In an embodiment, the pattern of the mandrel pattern 144 can be tuned by tuning X (i.e., by tuning the second depth D2). In an example where X=1 (i.e., where D2=W5), the mandrel pattern 144 is the 1:1:1:1 L/S pattern.

In an embodiment, a pattern of the mandrel pattern 144 can be transferred into the intermediate layer 104. For example, the intermediate layer 104 can be etched by an anisotropic etching process, such as reactive ion etch (RIE), while using the mandrel pattern 144 as an etch mask. In an embodiment, the transferred pattern can be used to form a contact hole, a via, a metal line, gate line, isolation region, and other features useful in semiconductor fabrication, for example.

Anti-spacer process flows and reversible overcoats are disclosed in (1) U.S. Provisional Application No. 63/555,246, filed on Feb. 19, 2024, (2) U.S. Provisional Application No. 63/603,580, filed on Nov. 28, 2023, (3) U.S. application Ser. No. 18/615,313, filed on Mar. 25, 2024, and (4) U.S. application Ser. No. 18/617,951, filed on Mar. 27, 2024, each of which applications are hereby incorporated herein by reference in their entirety.

For a suitable reversible overcoat (ROC) layer material, a suitable developer can be selected for selectively removing de-crosslinked regions of converted reversible overcoat layer while leaving unmodified regions of nonconverted reversible overcoat layer and patterned photoresist intact. In an embodiment of the present disclosure, 4-methyl-2-pentanol or methyl isobutyl carbinol (MIBC) (e.g., CAS #108-11-2) can be selected as a suitable developer for many suitable reversible overcoat layer materials, such as a ROC layer including a first material of a phenolic functional group and a second material of a vinyl ether functional group, or such as a ROC layer including a first material of a methacrylic acid functional group and a second material of a vinyl ether functional group, for example. However, an embodiment of the present disclosure is not necessarily limited to these example ROC layer materials.

In an embodiment of the present disclosure, a suitable developer can be selected that has solvent characteristics similar to MIBC but may be selected based on other favorable characteristics of the material, such as being non-flammable, being non-toxic, being more environmentally friendly (sustainability), providing good environmental, health, and safety specifications, providing shorter or longer chemical reaction time, providing greater selectivity for certain selected ROC layer materials, available at lower cost, more available and/or at lower cost for certain factory locations, providing favorable temperature usage requirements, or providing more precise or smoother surface after removal of the developed material, or any combination thereof, for example. In an embodiment of the present disclosure, a suitable developer can be a combination of two or more materials that when combined have solvent characteristics similar to MIBC but may be selected based on other favorable characteristics of the material (such as those example characteristics listed above).

To select a suitable developer, Hansen Solubility Parameters can be considered and/or used for determining whether a given solvent or a given combination of two or more materials has solvent characteristics similar to MIBC for a given ROC layer material or group of ROC layer materials.

Hansen Solubility Parameters (HSP) are a set of three parameters that can predict the solubility of materials, particularly polymers, in different solvents. The principal behind HSP is based on like-dissolves-like principles (i.e., materials with similar solubility parameters are likely to dissolve in each other). The first parameter that makes up HSP is a dispersion forces parameter (8D), which represents the Van der Waals forces or dispersion forces that are present in all molecules. The second parameter that makes up HSP is a polar forces parameter (δP), which represents the dipole-dipole interactions between polar molecules. The third parameter that makes up HSP is a hydrogen bonding parameter (δH), which represents the hydrogen bonding potential of the molecules.

These three parameters of HSP can be used to create a 3D space, which can be referred to as a Hansen space or HSP space, where solvents and solutes can be mapped. For example, a software called HSPiP or Hansan Solubility Parameters in Practice, can be used to determine how closely a solvent or mixture matches a target.

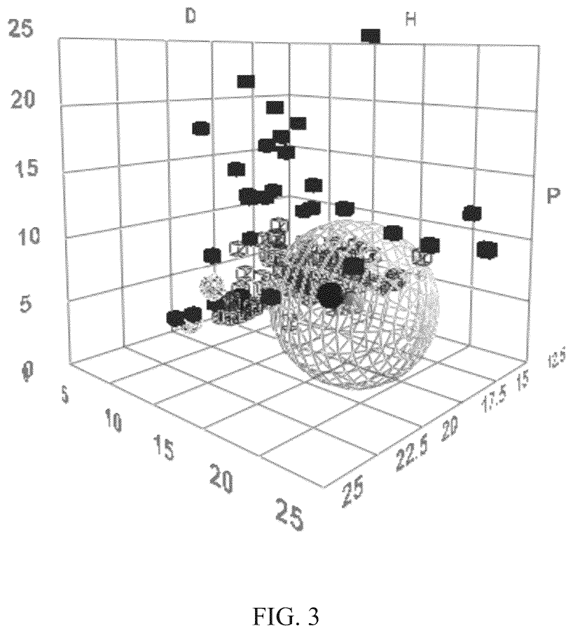

FIG. 3 is a three-dimension (3D) graph illustrating a Hansen Solubility Parameter (HSP) space in accordance with an embodiment of the present disclosure. More specifically, FIG. 3 shows an example HSP space mapped for a group of potential solvents related to a given solute with a sphere having a center point at the HSP mapped point for MIBC. A radius of the sphere shown in FIG. 3 can represent a distance from the reference point in the HSP space for MIBC. Accordingly, solvents or combinations of materials that have an HSP solvent value relative to a particular material or within a “distance” of a reference point for MIBC on an HSP mapping (i.e., within a sphere on a 3D HSP mapping or within a radius distance of a sphere having a center point at MIBC as a reference point) can be considered similar enough to be substituted for MIBC or as a suitable alternative for MIBC for a given ROC layer material. In the context of an embodiment of the present disclosure, a “distance” for a solubility distance of a solvent relative to MIBC in an HSP space, or for a combined solubility distance of a combination of two or more materials relative to MIBC in an HSP space, is an absolute distance (positive number) (i.e., irrespective of the location on the 3D plot relative to MIBC).

In an embodiment, a solubility distance for a solvent in a range of zero to seven from MIBC in an HSP space can be considered compatible and useable. In an embodiment, a combined solubility distance for a combination of two or more materials, in a range of zero to seven from the solubility values of MIBC in an HSP space can be considered compatible and useable; however, solvents or combination of materials having a greater solubility distance (e.g., up to 10) can be also effective in some embodiments or applications. Alternatively, in an embodiment, a solubility distance for a solvent in a range from zero to an upper limit of three, four, or five (e.g., 0-3, 0-4, or 0-5) from MIBC in an HSP space can be considered compatible and useable. And alternatively, in an embodiment, a combined solubility distance for a combination of two or more materials, in a range from zero to an upper limit of three, four, or five (e.g., 0-3, 0-4, or 0-5) from the solubility values of MIBC in an HSP space can be considered compatible and useable. Generally, a lower number for the solubility distance or combined solubility distance relative to MIBC in an HSP space can be a better selection for better compatibility and/or better performance, as compared to those with a higher number closer to the upper limit for distance.

The concept of “distance” herein also includes non-solvents that when combined provide combined solubility parameters similar to MIBC (e.g., with a combined solubility distance relative to MIBC of seven or less). The 3D plot in FIG. 3 shows the solvent parameters for numerous other solvents plotted graphically (square-shaped plotted points) with respect to an MIBC plotted point and a sphere around MIBC plotted point (i.e., with a center point of the sphere being the plotted point for MIBC). Through simulations using an HSPIP software, it has been shown that two or more non-solvents can be combined and the mathematical product and actual solubility of those combined materials in practice can mimic that of a given solvent such as MIBC and/or can be sufficiently similar in solvent characteristics relative to MIBC (e.g., within seven or less distance from MIBC in an HSP space).

Thus, for an embodiment of present disclosure, an HSP solubility space with a distance in a range of zero to seven relative to MIBC can be defined as a set of individual solvents and/or combinations of materials/solvents that can provide same or similar solvent characteristics as MIBC, for example. As illustrated in FIG. 3, this can be visualized by a sphere with a given radius (e.g., radius=seven distance units) when mapped in a 3D plot for HSP solubility values relative to MIBC, with MIBC being at the center of the sphere as a reference point. Accordingly, for an embodiment of the present disclosure, solvents (which can include combinations of solvents and/or non-solvents) that are close to each other in an HSP space can be likely to dissolve similar solutes, and materials close in Hansen space can be considered to be compatible for a given semiconductor process flow, for example.

Referring to FIG. 3, the HSP values for MIBC as a center point of the sphere (as a reference point) can be δD with 15.4, δP with 3.3, and δH with 12.3. Using HSP, the solubility distance of a solvent (e.g., where the solvent may be the suitable developer) can be calculated using Equation 1:

$$Dist = \sqrt{4 {( δ Dt - δ Di )}^{2} + {( δ Pt - δ Pi )}^{2} + {( δ Ht - δ Hi )}^{2}} \qquad Equation l$$

where Dist represents the solubility distance of the solvent, i represents the solvent, t represents a target (e.g., MIBC), δDt and δDi represent dispersion forces for the i^{th} chemical and the target respectively, δPt and δPi represent dipole-dipole interactions between polar molecules for the i^{th} chemical and the target respectively, and δHt and δHi represent hydrogen bonding potential of molecules for the i^{th} chemical and the target respectively.

Combined solubility distance for HSP solubility values in a range of zero to seven relative to MIBC in an HSP space can refer to a specific range of solubility compatibility between different substances combined and MIBC using Hansen Solubility Parameters (HSP).

In a process of calculating the combined solubility distance of a combination of two or more materials relative to a target substance in Hansen solubility space, the mixture's average solubility parameters can be computed first. “Materials” is being used generically in this context because a combination of two or more materials can include a combination of solvents, can include a combination of non-solvents, and/or can include a combination of non-solvent(s) and/or solvent(s), that then act as a suitable solvent for a given application (e.g., relative to MIBC).

Assuming a mixture of two materials (material 1 and material 2), with volume fractions f1 and f2 (where f1+f2=1), the combined solubility parameters (δDₘᵢₓ, δPₘᵢₓ, δHₘᵢₓ) for HSP values can be calculated using Equations 2-1, 2-2, and 2-3:

$$δ {D}_{mix} = {f}_{1} δ {D}_{1} + {f}_{2} δ {D}_{2} \qquad Equation 2 - 1$$

$$δ {P}_{mix} = {f}_{1} δ {P}_{1} + {f}_{2} δ {P}_{2} \qquad Equation 2 - 2$$

$$δ {H}_{mix} = {f}_{1} δ {H}_{1} + {f}_{2} δ {H}_{2} \qquad Equation 2 - 3$$

where δDₘᵢₓ represents weighted dispersion forces for the mixture of material 1 and material 2, δD1 and δD2 represent the individual dispersion forces for material 1 and material 2 respectively, δPₘᵢₓ represents weighted dipole-dipole interactions between polar molecules for the mixture of material 1 and material 2, δP1 and δP2 represent the individual dipole-dipole interactions between polar molecules for material 1 and material 2 respectively, δHₘᵢₓ represents weighted hydrogen bonding potential of molecules for the mixture of material 1 and material 2, δH1 and δH2 represent the individual hydrogen bonding potential of molecules for material 1 and material 2 respectively.

After the weighted average solubility parameters of the mixture are determined, the combined solubility distance between the target material (e.g., MIBC) and the mixture (in an HSP space that can be graphically represented in a 3D plot, for example) can be calculated using the same equation for the solubility distance (i.e., Equation 1 noted above) but using the weighted mixture parameters described above (i.e., Equations 2-1, 2-2, and 2-3) in Equation 3:

$$Dist = \sqrt{4 {( δ Dt - δ Dmix )}^{2} + {( δ Pt - δ Pmix )}^{2} + {( δ Ht - δ Hmix )}^{2}} \qquad Equation 3$$

where Dist represents the combined solubility distance, δDt represents dispersion forces for MIBC, δPt represents dipole-dipole interactions between polar molecules for MIBC, and δHt represents hydrogen bonding potential of molecules for MIBC.

And more generally for a mixture of more than two materials, the process for calculating the combined solubility distance relative to MIBC in an HSP space is similar. First, the volume fractions (fᵢ) of each material of the mixture can be determined. Second, the weighted average solubility parameters can be computed using equations 4-1, 4-2, and 4-3:

$$δ {D}_{mix} = {\sum }_{i} {f}_{i} δ {D}_{i} \qquad Equation 4 - 1$$

$$δ {P}_{mix} = {\sum }_{i} {f}_{i} δ {P}_{i} \qquad Equation 4 - 2$$

$$δ {H}_{mix} = {\sum }_{i} {f}_{i} δ {H}_{i} \qquad Equation 4 - 3$$

where δDₘᵢₓ represents weighted dispersion forces for the mixture of materials, δDᵢ represents the individual dispersion forces for each material of the mixture, δPₘᵢₓ represents weighted dipole-dipole interactions between polar molecules for the mixture of materials, δPᵢ represents the individual dipole-dipole interactions between polar molecules for each material of the mixture, δHₘᵢₓ represents weighted hydrogen bonding potential of molecules for the mixture of materials, and δHᵢ represents the individual hydrogen bonding potential of molecules for each material of the mixture.

Third, the combined solubility distance between the target material (e.g., MIBC) and the mixture can be calculated using the same equation for the solubility distance using the weighted mixture parameters described above (i.e., Equations 4-1, 4-2, and 4-3) in Equation 3 (see above).

In an embodiment, the determination or calculation of the combined solubility distance can be achieved by an HSPiP computer program using different weighting techniques and/or different equations than any of or all of the example equations described above, and/or using numerical approximations or numerical methods for determining/calculating HSP information. For example, an HSPiP computer program may make use of lookup tables for parts of or all of the data used for determining the combined solubility distance. For example, an HSPiP computer program may make use of numerical methods to approximate the results of a mathematical equation.

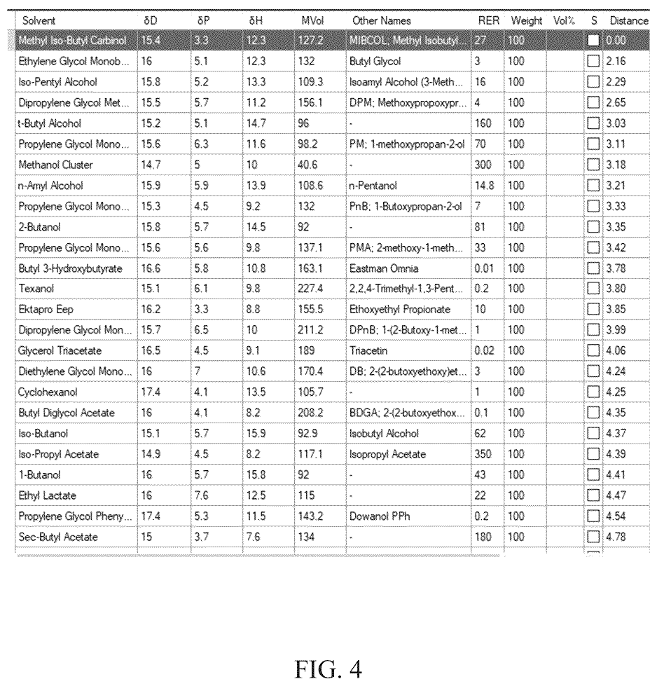

FIG. 4 is a screenshot from an HSPiP computer program providing a list of materials including HSP information in accordance with an embodiment of the present disclosure. More specifically, FIG. 4 shows a list of materials (e.g., solvents), with MIBC being at the top of the list. The column on the far right is labeled “Distance,” which is the solubility distance of each listed material relative to MIBC calculated using Equation 1 (described above) in an HSP space (see e.g., HSP space illustrated graphically in FIG. 3). Hence, the solubility distance for MIBC relative to MIBC is zero. All of the example materials listed in FIG. 4 have a solubility distance relative to MIBC of less than seven. And hence, each of the example materials listed in FIG. 4 can be suitable developers (or suitable alternatives for MIBC) for a given ROC layer material in accordance with an embodiment of the present disclosure.

Referring to FIG. 4, the smaller the solubility distance value of a solvent in the Distance column, the more similar the solubility characteristics can be to MIBC, which can be set as the target (or a “distance” of zero). Accordingly, distance values can be compared to MIBC as a reference material/solvent/developer. Note that this list in FIG. 4 is not an exhaustive list of similar solvents but simply an example list for illustration purposes. Many other solvents and/or material/solvent combinations can be identified using HSPIP software, and using other material/solvent combinations.

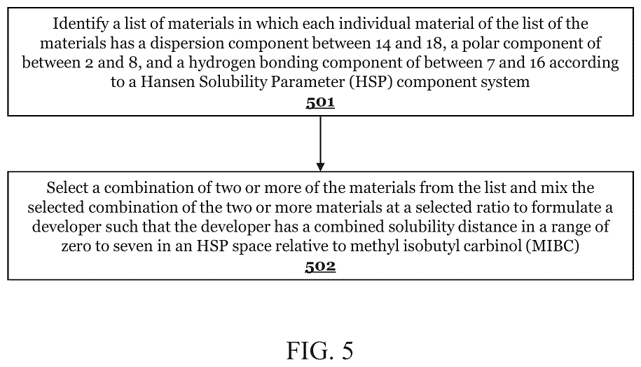

FIG. 5 is a flowchart illustrating a method for selecting a developer in accordance with an embodiment of the present disclosure. In a method embodiment of formulating a developer for developing a patterning material having a reversible solubility in a process of manufacturing a semiconductor device, the method can include identifying a list of materials in which each individual material of the list of the materials has a dispersion component (δD) between 14 and 18, a polar component (δP) of between 2 and 8, and a hydrogen bonding component (δH) of between 7 and 16 according to an HSP component system (box 501). In a method embodiment of formulating a developer, the method can include selecting a combination of two or more of the materials from the list and mixing the selected combination of the two or more materials at a selected ratio to formulate the developer such that the developer has a combined solubility distance in a range of zero to seven in an HSP space relative to MIBC (box 502).

In a method embodiment of formulating a developer, a first solubility distance of one of the two or more materials alone can be greater than seven, while the combined solubility distance based on the combination of the two or more materials is within the range of zero to seven in the HSP space relative to MIBC. In a method embodiment of formulating a developer, for the combination of the two or more materials of the developer, it can be that none of the materials is MIBC.

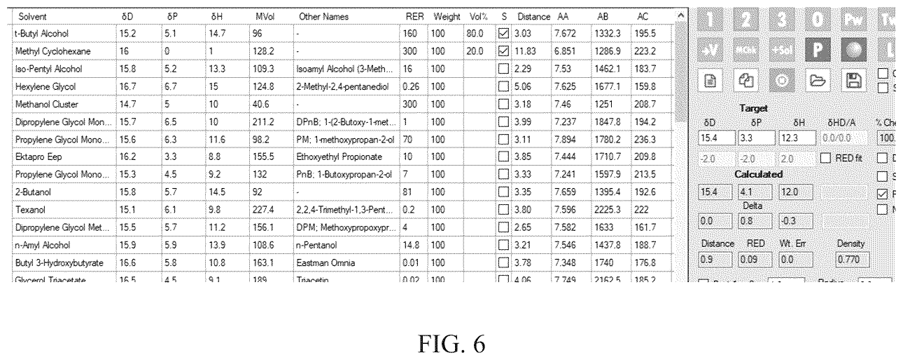

FIG. 6 is a screenshot from an HSPiP computer program providing an example combination of materials including HSP information for each listed material, in accordance with an embodiment of the present disclosure. FIG. 6 shows an example of a solvent mixture, where each solvent has a larger solubility distance individually (3 and 11.8 respectively) in the HSP space relative to MIBC than the combined solubility distance in the HSP space relative to MIBC. In this example case, two solvents are mixed to give a combined solubility distance of 0.9 from MIBC, as shown in FIG. 6 for example. In practice, two or three or more solvents can be combined.

There can be many possible combinations, but acceptable combinations can be identified using an HSPiP software from a given vendor for example. A solvent mixture can be selected based on a combination of practicality and combined solubility distance in the HSP space relative to MIBC. There are other solvent properties, such as toxicity and flammability, for example, that may restrict or deter solvent choices for a developer, for example.

An embodiment of the present disclosure can make use of techniques disclosed herein for methods and compositions of developing reversible overcoat films. Such techniques can include using 4-methyl-2-pentanol (MIBC/methyl isobutyl carbinol CAS #108-11-2) as a developer for certain reversible overcoat materials. Developers for such materials can be challenging because, in some embodiments, a developer should be capable to dissolve deprotected reversible solubility material, without dissolving remaining reversible solubility material or photoresist material on the substrate. Such techniques also can include solvent compositions, and methods of using such compositions, that have an HSP solubility distance close to MIBC or similar solubility characteristics as MIBC.

An embodiment of the present disclosure can be applied to an area of advanced pattern formation methods where a pattern is formed by the placement of an overcoat with inverse solubility on a relief pattern of a photoresist and an anti-spacer is formed. The anti-spacer trench can be formed through track-based patterning methods. An embodiment of the present disclosure can provide an advantage of selecting an anti-spacer developer that is neither aqueous based tetramethyl ammonia hydroxide (TMAH) or n-butyl acetate (nBA). Instead, the developer can be 4-methyl-2-pentanol (MIBC/methyl isobutyl carbinol CAS #108-11-2), or any solvent or combination of solvents/materials that have a same or similar solubility characteristics in HSP solubility space as MIBC. In an anti-spacer process flow, a develop operation to form or reveal trenches can use MIBC or MIBC-like solvent as a developer in accordance with an embodiment of the present disclosure, and such developer can be formulated/selected such that that the developer does not readily dissolve the initial trimmed photoresist pattern nor the second layer pattern (e.g., crosslinked reversible overcoat material) (e.g., having an etch selectivity that is much greater, or 100×).

Accordingly, techniques disclosed herein include using 4-methyl-2-pentanol solvent and its solvent space for use as a developer in the formation of an anti-spacer trenches, in accordance with an embodiment of the present disclosure. This MIBC solvent space can include any solvent or combination of solvents/materials that are similar to MIBC in HSP space and have a mathematical distance (e.g., according to the distance formulas described herein) in a range of zero to seven from MIBC. Having such a developer can be useful in an anti-spacer process to remove an acid diffusion region while retaining materials and structures forming a mandrel pattern (see e.g., mandrel pattern 144 including trimmed mandrels 122 and secondary mandrels 136 in FIG. 1I).

Even though MIBC can be used as a top-coat solvent or part of a top-coat composition, an embodiment of the present disclosure provides a method for using MIBC in a different way (for a different purpose to solve a different problem/issue) as a developer. MIBC typically does not dissolve commonly used or standard photoresist materials, and thus MIBC can be used as a type of etchant for selectively removing a certain material without affecting the photoresist material (e.g., in a track-based anti-spacer process flow). By creating a solubility switch in the ROC layer, the MIBC can be used as a developer to selectively remove switched/converted material for patterning. Even though a developer is typically used after a change in material after a photo step (e.g., changing photoresist with light or radiation exposure), in the context of an embodiment of the present disclosure, a developer can be used after a change in material by a diffusion (e.g., the pattern in a ROC layer is defined by chemical diffusion rather than by a photo step).

Accordingly, an embodiment of the present disclosure is not necessarily limited to the anti-spacer process flow described above and illustrated in FIGS. 1A-1I. A developer in accordance with an embodiment of the present disclosure can be used in any process flow or patterning operation in which a layer has portions that are solubility switched or chemically converted and then the switched/converted material becomes soluble to MIBC, or becomes soluble to a combination of two or materials within a given solubility distance from MIBC in an HSP space, such that the developer can remove the switched/converted material while leaving the unconverted material and/or photoresist mandrels intact for creating a new mandrel pattern. For example, in an embodiment, the switched/converted material can be from a cross-linked to de-cross-linked switch of an ROC material (as described above relating to FIGS. 1A-1I). However, in an embodiment, the switched/converted material can be switched/converted by another way or from a different starting point or material composition. For example, in an embodiment, the solubility switch or conversion of material can be, generally, from a diffusion of a species or element(s) (e.g., acid) in a first material from that that first material into a second material, where the second material is experiencing the solubility switch to a given depth into the second material that allows the switched/converted material (or portion) to become soluble to MIBC, or to become soluble to a combination of two or materials within a given solubility distance from MIBC in an HSP space. Accordingly, the switching mechanism and/or process for making the switched/converted material soluble to MIBC (or MIBC similar solvent(s)) can vary for other embodiments.

In the preceding description, specific details have been set forth, such as a particular geometry of a processing system and descriptions of various components and processes used therein for example embodiments. It can be understood, however, that techniques herein may be practiced in other embodiments and other process flows that depart from these specific example details, and that such example details can be for purposes of explanation and not necessarily limitation. Example embodiments disclosed herein have been described with reference to the accompanying drawings. Similarly, for purposes of explanation, specific numbers, materials, and configurations have been set forth to provide a thorough understanding, but other embodiments may be practiced without such specific details.

Various techniques have been described as multiple discrete operations to assist in understanding the various example embodiments. The order of description should not be construed as to imply that these operations are necessarily order dependent. Indeed, these operations need not be performed in the order of presentation. Operations described may be performed in a different order than the described example embodiments. Various additional operations may be performed and/or described operations may be omitted in other embodiments.

“Substrate” as used herein can generically refer to an object being processed in accordance with the invention. The substrate can include any material portion or structure of a device, and can particularly include a semiconductor or other electronics device, and can, for example, be a base substrate structure, such as a semiconductor wafer, reticle, and/or a layer on or overlying a base substrate structure, such as a thin film. Thus, substrate is not limited to any particular base structure, underlying layer or overlying layer, patterned or un-patterned structure, or intermediate structure during fabrication of semiconductor devices, or combinations thereof, and can include any such layer or base structure, and any combination of layers and/or base structures. The present disclosure can reference particular types of substrates, but such can be for illustrative purposes only.

More example embodiments of the present disclosure are summarized here. Other embodiments can also be understood from the entirety of the specification as well as the claims filed herein.

Example 1. A developer configured to selectively remove a solubility switched region of a layer of a first material during a semiconductor manufacturing process for forming a mandrel pattern in the layer on a substrate, where the developer has a solubility distance in a range of zero to seven in a Hansen Solubility Parameter (HSP) space relative to methyl isobutyl carbinol (MIBC).

Example 2. The developer of example 1, where the developer is MIBC.

Example 3. The developer of one of examples 1 or 2, where the developer includes a combination of two or more materials, and where the solubility distance is a combined solubility distance based on the combination of the two or more materials.

Example 4. The developer of one of examples 1 to 3, where for the combination of the two or more materials, none of the materials is MIBC.

Example 5. The developer of one of examples 1 to 4, where the developer is a combination of two or more materials, where the solubility distance is a combined solubility distance based on the combination of the two or more materials, and where a first solubility distance of one of the two or more materials alone is greater than seven, but the combined solubility distance based on the combination of the two or more materials is within the range of zero to seven in the HSP space relative to MIBC.

Example 6. The developer of one of examples 1 to 5, where for the combination of the two or more materials, none of the materials is MIBC.

Example 7. The developer of one of examples 1 to 6, where the developer is a combination of two or more materials, where the solubility distance is a combined solubility distance based on the combination of the two or more materials, and where each individual material of a list of the materials has a dispersion component between 14 and 18, a polar component of between 2 and 8, and a hydrogen bonding component of between 7 and 16 according to an HSP component system.

Example 8. The developer of one of examples 1 to 7, where for the combination of the two or more materials, none of the materials is MIBC.

Example 9. In a method for forming a semiconductor device, the method includes coating a reversible overcoat layer over first mandrels on a substrate, inducing a crosslinking reaction within the reversible overcoat layer that renders the reversible overcoat layer insoluble to a developer and forms a crosslinked overcoat layer, diffusing acid particles from the first mandrels into first portions of the crosslinked overcoat layer, inducing a de-crosslinking reaction within the first portions of the crosslinked overcoat layer to form de-crosslinked regions, where unmodified regions of the crosslinked overcoat layer form second mandrels, and selectively removing the de-crosslinked regions with the developer such that the first mandrels and the second mandrels form a mandrel pattern over the substrate, where the developer has a solubility distance in a range of zero to seven in a Hansen Solubility Parameter space relative to methyl isobutyl carbinol (MIBC).

Example 10. The method of example 9, where the developer is MIBC.

Example 11. The method of one of examples 9 or 10, further including selecting the developer, where the developer is a combination of two or more materials that are not MIBC, and where the solubility distance is a combined solubility distance based on the combination of the two or more materials.

Example 12. The method of one of examples 9 to 11, where the selecting of the developer further includes selecting the combination of the two or more materials, determining the combined solubility distance of the combination of the two or more materials, and determining whether the combination of the two or more materials is suitable as the developer based on whether the combined solubility distance of the combination of the two or more materials is within the range of zero to seven in the Hansen Solubility Parameter space relative to MIBC.

Example 13. The method of one of examples 9 to 12, where the selecting of the developer is performed using a computer software program.

Example 14. The method of one of examples 9 to 13, further including selecting the developer, where the developer is a combination of two or more materials that are not MIBC, where the solubility distance is a combined solubility distance based on the combination of the two or more materials, and where a first solubility distance of one of the two or more materials alone is greater than seven, but the combined solubility distance based on the combination of the two or more materials is within the range of zero to seven in the Hansen Solubility Parameter space relative to MIBC.

Example 15. The method of one of examples 9 to 14, where the reversible overcoat layer includes a first material of a phenolic functional group and a second material of a vinyl ether functional group.

Example 16. The method of one of examples 9 to 15, where the reversible overcoat layer includes a first material of a methacrylic acid functional group and a second material of a vinyl ether functional group.

Example 17. The method of one of examples 9 to 16, further including forming the first mandrels on the substrate using a sub-lithography trimming process, and generating the acid particles within the first mandrels by exposure to actinic radiation.

Example 18. In a method of formulating a developer for developing a patterning material having a reversible solubility in a process of manufacturing a semiconductor device, the method includes identifying a list of materials in which each individual material of the list of the materials has a dispersion component between 14 and 18, a polar component of between 2 and 8, and a hydrogen bonding component of between 7 and 16 according to a Hansen Solubility Parameter (HSP) component system, and selecting a combination of two or more of the materials from the list and mixing the selected combination of the two or more materials at a ratio to formulate the developer such that the developer has a combined solubility distance in a range of zero to seven in an HSP space relative to methyl isobutyl carbinol (MIBC).

Example 19. The method of example 18, where a first solubility distance of one of the two or more materials alone is greater than seven, but the combined solubility distance based on the combination of the two or more materials is within the range of zero to seven in the HSP space relative to MIBC.

Example 20. The method of one of examples 18 or 19, where for the combination of the two or more materials, none of the materials is MIBC.

While illustrative and example embodiments have been described with reference to illustrative drawings, this description is not intended to be construed in a limiting sense. Various modifications and combinations of the illustrative and example embodiments, as well as other embodiments, can be apparent to persons skilled in the pertinent art upon referencing the present disclosure. It is therefore intended that the appended claims encompass any and all of such modifications, equivalents, or embodiments.

What is claimed is:

1. A developer comprising a developer composition configured to selectively remove a solubility switched region of a layer of a first material during a semiconductor manufacturing process for forming a mandrel pattern in the layer on a substrate, wherein the developer composition has a solubility distance in a range of zero to seven in a Hansen Solubility Parameter (HSP) space relative to methyl isobutyl carbinol (MIBC).

2. The developer of claim 1, wherein the developer composition comprises MIBC.

3. The developer of claim 1, wherein the developer composition comprises a combination of two or more materials, and wherein the solubility distance is a combined solubility distance based on the combination of the two or more materials.

4. The developer of claim 3, wherein for the combination of the two or more materials, none of the materials is MIBC.

5. The developer of claim 1, wherein the developer composition comprises a combination of two or more materials, wherein the solubility distance is a combined solubility distance based on the combination of the two or more materials, and wherein a first solubility distance of one of the two or more materials alone is greater than seven, but the combined solubility distance based on the combination of the two or more materials is within the range of zero to seven in the HSP space relative to MIBC.

6. The developer of claim 5, wherein for the combination of the two or more materials, none of the materials is MIBC.

7. The developer of claim 1, wherein the developer composition comprises a combination of two or more materials, wherein the solubility distance is a combined solubility distance based on the combination of the two or more materials, and wherein each individual material of a list of the materials has a dispersion component between 14 and 18, a polar component of between 2 and 8, and a hydrogen bonding component of between 7 and 16 according to an HSP component system.

8. The developer of claim 7, wherein for the combination of the two or more materials, none of the materials is MIBC.

9. A method for forming a semiconductor device, the method comprising:
coating a reversible overcoat layer over first mandrels on a substrate;
inducing a crosslinking reaction within the reversible overcoat layer that renders the reversible overcoat layer insoluble to a developer and forms a crosslinked overcoat layer;
diffusing acid particles from the first mandrels into first portions of the crosslinked overcoat layer;
inducing a de-crosslinking reaction within the first portions of the crosslinked overcoat layer to form de-crosslinked regions, wherein unmodified regions of the crosslinked overcoat layer form second mandrels; and
selectively removing the de-crosslinked regions with the developer such that the first mandrels and the second mandrels form a mandrel pattern over the substrate, wherein the developer has a solubility distance in a range of zero to seven in a Hansen Solubility Parameter space relative to methyl isobutyl carbinol (MIBC).

10. The method of claim 9, wherein the developer is MIBC.

11. The method of claim 9, further comprising selecting the developer, wherein the developer is a combination of two or more materials that are not MIBC, and wherein the solubility distance is a combined solubility distance based on the combination of the two or more materials.

12. The method of claim 11, wherein the selecting of the developer further comprises:
selecting the combination of the two or more materials;
determining the combined solubility distance of the combination of the two or more materials; and
determining whether the combination of the two or more materials is suitable as the developer based on whether the combined solubility distance of the combination of the two or more materials is within the range of zero to seven in the Hansen Solubility Parameter space relative to MIBC.

13. The method of claim 11, wherein the selecting of the developer is performed using a computer software program.

14. The method of claim 9, further comprising selecting the developer, wherein the developer is a combination of two or more materials that are not MIBC, wherein the solubility distance is a combined solubility distance based on the combination of the two or more materials, and wherein a first solubility distance of one of the two or more materials alone is greater than seven, but the combined solubility distance based on the combination of the two or more materials is within the range of zero to seven in the Hansen Solubility Parameter space relative to MIBC.

15. The method of claim 9, wherein the reversible overcoat layer comprises a first material of a phenolic functional group and a second material of a vinyl ether functional group.

16. The method of claim 9, wherein the reversible overcoat layer comprises a first material of a methacrylic acid functional group and a second material of a vinyl ether functional group.

17. The method of claim 9, further comprising:
forming the first mandrels on the substrate using a sub-lithography trimming process; and
generating the acid particles within the first mandrels by exposure to actinic radiation.

18. A method of formulating a developer for developing a patterning material having a reversible solubility in a process of manufacturing a semiconductor device, the method comprising:
identifying a list of materials in which each individual material of the list of the materials has a dispersion component between 14 and 18, a polar component of between 2 and 8, and a hydrogen bonding component of between 7 and 16 according to a Hansen Solubility Parameter (HSP) component system; and
selecting a combination of two or more of the materials from the list and mixing the selected combination of the two or more materials at a ratio to formulate the developer such that the developer has a combined solubility distance in a range of zero to seven in an HSP space relative to methyl isobutyl carbinol (MIBC).

19. The method of claim 18, wherein a first solubility distance of one of the two or more materials alone is greater than seven, but the combined solubility distance based on the combination of the two or more materials is within the range of zero to seven in the HSP space relative to MIBC.

20. The method of claim 18, wherein for the combination of the two or more materials, none of the materials is MIBC.
